(19) United States
(12) Patent Application Publication
(10) Pub. No.: US 2018/0080999 A1
(43) Pub. Date: Mar. 22, 2018

(54) DETERMINING POWER ELECTRONICS FEASIBILITY WITH SINGLE TURN MAGNETIC SIMULATION DATA

(71) Applicant: QUALCOMM Incorporated, San Diego, CA (US)

(72) Inventors: Felix Weidner, Munich (DE); Wojciech Chlebosz, Taufkirchen (DE); Daniel Kuerschner, Grasbrunn (DE); Michael Werner, Markt Schwaben (DE); Martin Pavlovsky, Munchen (DE)

(21) Appl. No.: 15/272,673

(22) Filed: Sep. 22, 2016

(51) Int. Cl. G01R 31/40; H02J 50/12

(52) U.S. Cl. CPC G01R 31/40; H02J 50/12

(57) ABSTRACT

Techniques for determining power electronics feasibility in a wireless power transfer system with a transmitting element and a receiving element are provided. An example apparatus includes a processor configured to receive FEM simulation results for offset positions between the transmitting element and the receiving element, calculate a total real input current variation for the offset positions based on the FEM simulation results, calculate an indication of a difference between an ideal transmitting element current value and a real transmitting element current value for each of the offset positions based on the FEM simulation results, determine a maximum difference value based on the indication of the difference for each of the offset positions, and determine the power electronics feasibility based on the total real input current variation as compared to a total real input current variation threshold value, and the maximum difference value as compared to a maximum difference threshold value.

### FIELD

This application is generally related to wireless power transfer, and more specifically to methods and apparatuses for determining the feasibility of power electronic circuits based on analyzing single turn magnetic simulation data.

### BACKGROUND

An increasing number and variety of electronic devices are powered via rechargeable batteries. Such devices include mobile phones, portable music players, laptop computers, tablet computers, computer peripheral devices, communication devices (e.g., BLUETOOTH devices), digital cameras, hearing aids, vehicles, and the like. While battery technology has improved, battery-powered electronic devices increasingly require and consume greater amounts of power. As such, these devices frequently require recharging. Rechargeable devices are often charged via wired connections that require cables or other similar connectors that are physically connected to a power supply. Cables and similar connectors may sometimes be inconvenient or cumbersome and may have other drawbacks. Wireless power charging systems may allow users to charge and/or power electronic devices without physical, electro-mechanical connections, thus simplifying the use of the electronic device.

Larger appliances and vehicles may create additional circuit design complications because the larger currents and voltages can put more stress on the electrical components. Generally, electrical, mechanical and performance requirements for wireless electric vehicle charging (WEVC) systems are highly individual and customer specific. Manually designing each aspect of such systems can be time intensive. For example, the WEVC magnetics design may be influenced by power electronics components like semiconductors, tuning elements and litz wire. The stress on these components is limited due to thermal, packaging, cost and system efficiency aspects. It is desirable during the magnetic design phase to determine the feasibility of power electronics in a receiver circuit based on anticipated system stress.

### SUMMARY

An example of a method for determining a power electronics feasibility in a wireless including a transmitting element and a receiving element according to the disclosure includes at least one processor configured to receive Finite Element Method (FEM) simulation results for one or more offset positions between the transmitting element and the receiving element, calculate a total real input current variation for the one or more offset positions based on the FEM simulation results, calculate an indication of a difference between an ideal transmitting element current value and a real transmitting element current value for each of the one or more offset positions based on the FEM simulation results, determine a maximum difference value based on the indication of the difference for each of the one or more offset positions, and determine the power electronics feasibility based on the total real input current variation as compared to a total real input current variation threshold value, and the maximum difference value as compared to a maximum difference threshold value.

Implementations of such an apparatus may include one or more the following features. The total real input current variation threshold value may be between 2.0 and 2.5 and the maximum difference threshold value may be a maximum percentage difference value between 10% and 20%. The at least one processor may be further configured to calculate ideal tuning capacitor values for a resonant frequency at each of the one or more offset positions to calculate the indication of the difference between the ideal transmitting element current value and the real transmitting element current value for each of the one or more offset positions. The at least one processor may further configured to calculate real tuning capacitor values for a lowest coupling position to calculate the total real input current variation for the one or more offset positions. The FEM simulation results may include a coupling value, a transmitting element inductance value, a receiving element inductance value, and a receiving element current value for each of the one or more offset positions. A data structure may be operably connected to the at least one processor. The data structure may include a first field containing data representing an offset position, a second field containing data representing an ideal input current, a third field containing data representing a real input current, a fourth field containing data representing an ideal current through a the transmitting element, and a fifth field containing data representing a real current through the transmitting element.

An example of method for determining power electronics feasibility in a wireless power transfer system according to the disclosure includes determining a one or more offset positions between a transmitting element and a receiving element, receiving Finite Element Method (FEM) simulation results for the one or more offset positions between the transmitting element and the receiving element, calculating a total real input current variation for the one or more offset positions based on the FEM simulation results, calculating a difference between an ideal transmitting element current value and a real transmitting element current value for each of the one or more offset positions based on the FEM simulation results, determining a maximum difference value based on the difference for each of the one or more offset positions, and determining power electronics feasibility based on the total real input current variation as compared to a total real input current variation threshold value, and the maximum difference value as compared to a maximum difference threshold value.

Implementations of such a method may include one or more of the following features. The wireless power transfer system may be configured to provide a power out of 6.6 kW. The total real input current variation threshold value may be between 2.0 and 2.5 and the maximum difference threshold value may be a maximum percentage difference value between 10% and 20%. Calculating the difference between the ideal transmitting element current value and the real transmitting element current value for each of the one or more offset positions may include calculating ideal tuning capacitor values for a resonant frequency at each of the one or more offset positions. Calculating the total real input current variation for the one or more offset positions may include calculating real tuning capacitor values for a lowest coupling position, such that the lowest coupling position is one of the one or more offset positions with a lowest coupling value. The FEM simulation results may include a coupling value, a transmitting element inductance value, a receiving element inductance value, and a receiving element current value for each of the one or more offset positions. The total real input current variation and the maximum difference value may be stored in a data structure. The maximum difference value may be a maximum percentage difference value stored in a data structure.

An example of an apparatus for determining a power electronics feasibility in a wireless power transfer system including a transmitting element and a power receiving element according to the disclosure includes means for receiving Finite Element Method (FEM) simulation results for a one or more offset positions between the transmitting element and the receiving element, means for calculating a total real input current variation for the one or more offset positions based on the FEM simulation results, means for calculating an indication of a difference between an ideal transmitting element current value and a real transmitting element current value for each of the one or more offset positions based on the FEM simulation results, means for determining a maximum difference value based on the indication of the difference for each of the one or more offset positions, and means for determining the power electronics feasibility based on the total real input current variation as compared to a total real input current variation threshold value, and the maximum difference value as compared to a maximum difference threshold value.

An example of a non-transitory processor-readable storage medium comprising processor-readable instructions configured to cause a processor to determine power electronics feasibility in a wireless power transfer system according to the disclosure include code for determining a one or more offset positions between a transmitting element and a receiving element, code for receiving Finite Element Method (FEM) simulation results for the one or more offset positions between the transmitting element and the receiving element, code for calculating a total real input current variation for the one or more offset positions based on the FEM simulation results, code for calculating a difference between an ideal transmitting element current value and a real transmitting element current value for each of the one or more offset positions based on the FEM simulation results, code for determining a maximum difference value based on the difference for each of the one or more offset positions, and code for determining the power electronics feasibility based on the total real input current variation as compared to a total real input current variation threshold value, and the maximum difference value as compared to a maximum difference threshold value.

Implementations of such a non-transitory storage medium may include one or more of the following features. The wireless power transfer system may be configured to provide a power out of 6.6 kW. The total real input current variation threshold value may be between 2.0 and 2.5 and the maximum difference threshold value may be a maximum percentage difference value between 10% and 20%. The code for calculating the difference between the ideal transmitting element current value and the real transmitting element current value for each of the one or more offset positions may include code for calculating ideal tuning capacitor values for a resonant frequency at each of the one or more offset positions. The code for calculating the total real input current variation for the one or more offset positions may include code for calculating real tuning capacitor values for a lowest coupling position, such that the lowest coupling position is one of the one or more offset positions with a lowest coupling value. The FEM simulation results may include a coupling value, a transmitting element inductance value, a receiving element inductance value, and a receiving element current value for each of the one or more offset positions. The storage medium may include code for storing the total real input current variation and the maximum difference value in a data structure and/or code for storing a maximum percentage difference value in a data structure.

Items and/or techniques described herein may provide one or more of the following capabilities, as well as other capabilities not mentioned. The feasibility of the power electronics in a transmitter and in a receiver circuit may be determined via computer aid methods. Finite Element Methods (FEM) may be used to simulate the magnetic flux generated by a base pad. A computer aided single turn methodology may be used on the FEM results to determine an input current variation and a ratio of real and ideal base pad current values. Turn count data is not required for the single turn methodology. The feasibility of the power electronics in a receiver may be evaluated based on the input current variation and a ratio of real and ideal base pad current values without additional system knowledge. The number of physical prototype circuits to verify feasibility of the transmitter/receiver may be reduced. Transmitter/receiver design time may be reduced. Other capabilities may be provided and not every implementation according to the disclosure must provide any, let alone all, of the capabilities discussed. Further, it may be possible for an effect noted above to be achieved by means other than that noted, and a noted item/technique may not necessarily yield the noted effect.

### BRIEF DESCRIPTION OF THE DRAWINGS

FIG. 1 is a functional block diagram of an example of a wireless power transfer system.

FIG. 2 is a functional block diagram of an example of a passive/active rectifier in another wireless power transfer system.

FIG. 3 is a schematic diagram of an example of a portion of transmit circuitry or receive circuitry of the system shown in FIG. 2.

FIG. 4 is schematic diagram of an example of an equivalent circuit diagram of a parallel-parallel tuned wireless power transfer system at a single turn configuration (e.g., N_1=N_2=1).

FIG. 5A is a conceptual diagram of a base pad and examples of different offset positions.

FIG. 5B is a perspective diagram of an example of a transmitter and an offset single loop receiver.

FIG. 6 a flow diagram of an example of a process for determining a magnetic feasibility check based on a single turn analysis of magnetic FEM simulation data

FIG. 7 is a diagram of an example of a data structure for determining power electronics feasibility with single turn magnetic simulation data.

FIG. 8 is a flow diagram of an example of a process for determining the feasibility of a power electronics configuration.

FIG. 9 is a block diagram of a computer system for determining power electronics feasibility with single turn magnetic simulation data.

### DETAILED DESCRIPTION

Wireless power transfer may refer to transferring any form of energy associated with electric fields, magnetic fields, electromagnetic fields, or otherwise from a transmitter to a receiver without physical electrical conductors attached to and connecting the transmitter to the receiver to deliver the power (e.g., power may be transferred through free space). The power output into a wireless field (e.g., a magnetic field or an electromagnetic field) may be received, captured by, or coupled to by a power receiving element to achieve power transfer. The transmitter transfers power to the receiver through a wireless coupling of the transmitter and receiver.

FIG. 1 is a functional block diagram of an example of a wireless power transfer system 100. Input power 102 may be provided to a transmitter 104 from a power source (not shown in this figure) to generate a wireless (e.g., magnetic or electromagnetic) field 105 for performing energy transfer. A receiver 108 may couple to the wireless field 105 and generate output power 110 for storing or consumption by a device (not shown in this figure) that is coupled to receive the output power 110. The transmitter 104 and the receiver 108 are separated by a non-zero distance 112. The transmitter 104 includes a power transmitting element 114 configured to transmit/couple energy to the receiver 108. The receiver 108 includes a power receiving element 118 configured to receive or capture/couple energy transmitted from the transmitter 104.

The transmitter 104 and the receiver 108 may be configured according to a mutual resonant relationship. When the resonant frequency of the receiver 108 and the resonant frequency of the transmitter 104 are substantially the same, transmission losses between the transmitter 104 and the receiver 108 are reduced compared to the resonant frequencies not being substantially the same. As such, wireless power transfer may be provided over larger distances when the resonant frequencies are substantially the same. Resonant inductive coupling techniques allow for improved efficiency and power transfer over various distances and with a variety of inductive power transmitting and receiving element configurations.

The wireless field 105 may correspond to the near field of the transmitter 104. The near field corresponds to a region in which there are strong reactive fields resulting from currents and charges in the power transmitting element 114 that do not significantly radiate power away from the power transmitting element 114. The near field may correspond to a region up to about one wavelength of the power transmitting element 114. Efficient energy transfer may occur by coupling a large portion of the energy in the wireless field 105 to the power receiving element 118 rather than propagating most of the energy in an electromagnetic wave to the far field.

The transmitter 104 may output a time-varying magnetic (or electromagnetic) field with a frequency corresponding to the resonant frequency of the power transmitting element 114. When the receiver 108 is within the wireless field 105, the time-varying magnetic (or electromagnetic) field may induce a current in the power receiving element 118. As described above, with the power receiving element 118 configured as a resonant circuit to resonate at the frequency of the power transmitting element 114, energy may be efficiently transferred. An alternating current (AC) signal induced in the power receiving element 118 may be rectified to produce a direct current (DC) signal that may be provided to charge an energy storage device (e.g., a battery) or to power a load.

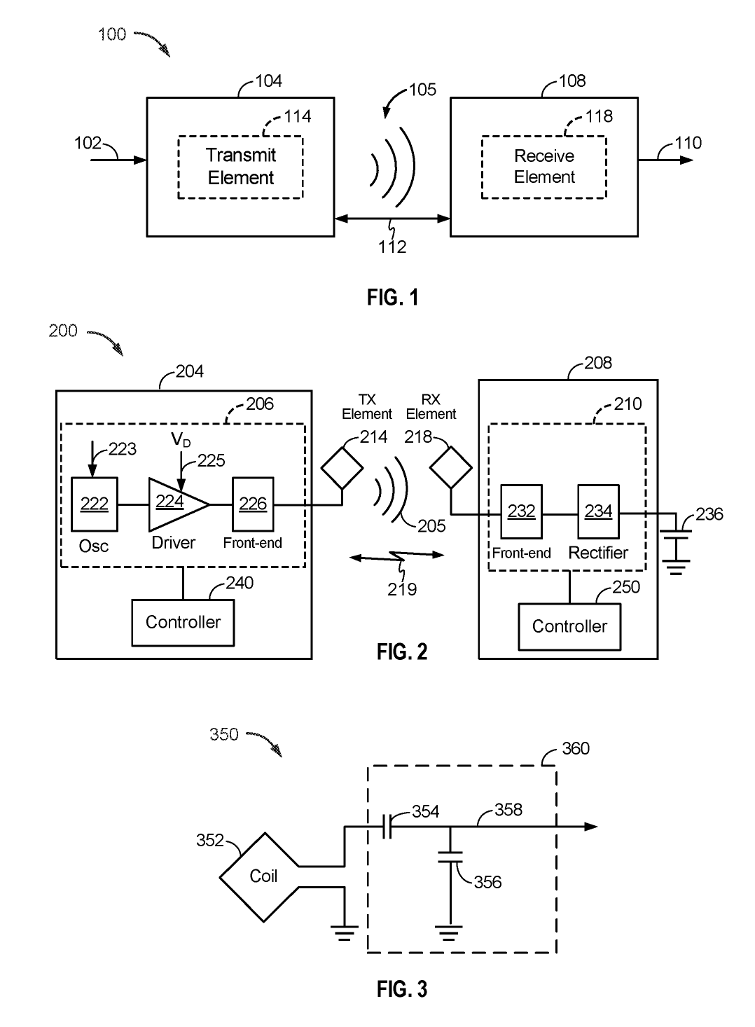

FIG. 2 is a functional block diagram of an example of a wireless power transfer system 200. The system 200 includes a transmitter 204 and a receiver 208. The transmitter 204 (also referred to herein as power transmitting unit) is configured to provide power to a power transmitting element 214 that is configured to transmit power wirelessly to a power receiving element 218 that is configured to receive power from the power transmitting element 214 and to provide power to the receiver 208. Despite their names, the power transmitting element 214 and the power receiving element 218, being passive elements, may transmit and receive power and communications.

The transmitter 204 includes the power transmitting element 214, transmit circuitry 206 that includes an oscillator 222, a driver circuit 224, and a front-end circuit 226. The power transmitting element 214 is shown outside the transmitter 204 to facilitate illustration of wireless power transfer using the power receiving element 218. The oscillator 222 may be configured to generate an oscillator signal at a desired frequency that may adjust in response to a frequency control signal 223. The oscillator 222 may provide the oscillator signal to the driver circuit 224. The driver circuit 224 may be configured to drive the power transmitting element 214 at, for example, a resonant frequency of the power transmitting element 214 based on an input voltage signal (V_{D}) 225. The driver circuit 224 may be a switching amplifier configured to receive a square wave from the oscillator 222 and output a sine wave.

The front-end circuit 226 may include a filter circuit configured to filter out harmonics or other unwanted frequencies. The front-end circuit 226 may include a matching circuit configured to match the impedance of the transmitter 204 to the impedance of the power transmitting element 214. As will be explained in more detail below, the front-end circuit 226 may include a tuning circuit to create a resonant circuit with the power transmitting element 214. As a result of driving the power transmitting element 214, the power transmitting element 214 may generate a wireless field 205 to wirelessly output power at a level sufficient for charging a battery 236, or powering a load.

The transmitter 204 further includes a controller 240 operably coupled to the transmit circuitry 206 and configured to control one or more aspects of the transmit circuitry 206, or accomplish other operations relevant to managing the transfer of power. The controller 240 may be a micro-controller or a processor. The controller 240 may be implemented as an application-specific integrated circuit (ASIC). The controller 240 may be operably connected, directly or indirectly, to each component of the transmit circuitry 206. The controller 240 may be further configured to receive information from each of the components of the transmit circuitry 206 and perform calculations based on the received information. The controller 240 may be configured to generate control signals (e.g., signal 223) for each of the components that may adjust the operation of that component. As such, the controller 240 may be configured to adjust or manage the power transfer based on a result of the operations performed by the controller 240. The transmitter 204 may further include a memory (not shown) configured to store data, for example, such as instructions for causing the controller 240 to perform particular functions, such as those related to management of wireless power transfer.

The receiver 208 includes the power receiving element 218, and receive circuitry 210 that includes a front-end circuit 232 and a rectifier circuit 234. The power receiving element 218 is shown outside the receiver 208 to facilitate illustration of wireless power transfer using the power receiving element 218. The front-end circuit 232 may include matching circuitry configured to match the impedance of the receive circuitry 210 to the impedance of the power receiving element 218. As will be explained below, the front-end circuit 232 may further include a tuning circuit to create a resonant circuit with the power receiving element 218. The rectifier circuit 234 may generate a DC power output from an AC power input to charge the battery 236, as shown in FIG. 3. The receiver 208 and the transmitter 204 may additionally communicate on a separate communication channel 219 (e.g., BLUETOOTH, ZIGBEE, cellular, etc.). The receiver 208 and the transmitter 204 may alternatively communicate via in-band signaling using characteristics of the wireless field 205.

The receiver 208 may be configured to determine whether an amount of power transmitted by the transmitter 204 and received by the receiver 208 is appropriate for charging the battery 236. The transmitter 204 may be configured to generate a predominantly non-radiative field with a direct field coupling coefficient (k) for providing energy transfer. The receiver 208 may directly couple to the wireless field 205 and may generate an output power for storing or consumption by a battery (or load) 236 coupled to the output or receive circuitry 210.

The receiver 208 further includes a controller 250 that may be configured similarly to the transmit controller 240 as described above for managing one or more aspects of the wireless power receiver 208. The receiver 208 may further include a memory (not shown) configured to store data, for example, such as instructions for causing the controller 250 to perform particular functions, such as those related to management of wireless power transfer.

As discussed above, transmitter 204 and receiver 208 may be separated by a distance and may be configured according to a mutual resonant relationship to try to minimize transmission losses between the transmitter 204 and the receiver 208.

FIG. 3 is a schematic diagram of an example of a portion of the transmit circuitry 206 or the receive circuitry 210 of FIG. 2. While a coil, and thus an inductive system, is shown in FIG. 3, other types of systems, such as capacitive systems for coupling power, may be used with the coil replaced with an appropriate power transfer (e.g., transmit and/or receive) element. As illustrated in FIG. 3, transmit or receive circuitry 350 includes a power transmitting or receiving element 352 and a tuning circuit 360. The power transmitting or receiving element 352 may also be referred to or be configured as an antenna such as a “loop” antenna. The term “antenna” generally refers to a component that may wirelessly output energy for reception by another antenna and that may receive wireless energy from another antenna. The power transmitting or receiving element 352 may also be referred to herein or be configured as a “magnetic” antenna, such as an induction coil (as shown), a resonator, or a portion of a resonator. The power transmitting or receiving element 352 may also be referred to as a coil or resonator of a type that is configured to wirelessly output or receive power. As used herein, the power transmitting or receiving element 352 is an example of a “power transfer component” of a type that is configured to wirelessly output and/or receive power. The power transmitting or receiving element 352 may include an air core or a physical core such as a ferrite core (not shown).

When the power transmitting or receiving element 352 is configured as a resonant circuit or resonator with tuning circuit 360, the resonant frequency of the power transmitting or receiving element 352 may be based on the inductance and capacitance. Inductance may be simply the inductance created by a coil and/or other inductor forming the power transmitting or receiving element 352. Capacitance (e.g., a capacitor) may be provided by the tuning circuit 360 to create a resonant structure at a desired resonant frequency. As a non-limiting example, the tuning circuit 360 may comprise a capacitor 354 and a capacitor 356, which may be added to the transmit or receive circuitry 350 to create a resonant circuit.

The tuning circuit 360 may include other components to form a resonant circuit with the power transmitting or receiving element 352. As another non-limiting example, the tuning circuit 360 may include a capacitor (not shown) placed in parallel between the two terminals of the circuitry 350. Still other designs are possible. For example, the tuning circuit in the front-end circuit 226 may have the same design (e.g., 360) as the tuning circuit in the front-end circuit 232. Alternatively, the front-end circuit 226 may use a tuning circuit design different than in the front-end circuit 232.

For power transmitting elements, the signal 358, with a frequency that substantially corresponds to the resonant frequency of the power transmitting or receiving element 352, may be an input to the power transmitting or receiving element 352. For power receiving elements, the signal 358, with a frequency that substantially corresponds to the resonant frequency of the power transmitting or receiving element 352, may be an output from the power transmitting or receiving element 352. Although aspects disclosed herein may be generally directed to resonant wireless power transfer, persons of ordinary skill will appreciate that aspects disclosed herein may be used in non-resonant implementations for wireless power transfer.

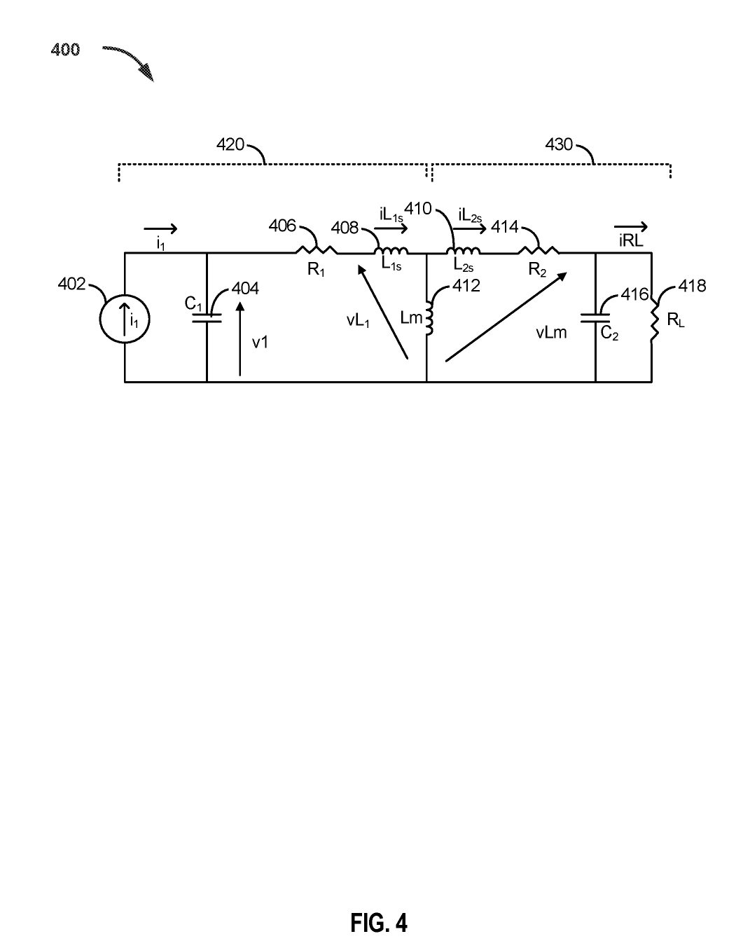

Referring to FIG. 4, an equivalent circuit diagram of a parallel-parallel tuned wireless power transfer system 400, as viewed from the primary side is shown. The wireless power transfer system 400 includes a wireless power transmitter 420 and a wireless power receiver 430. The wireless power transmitter 420 may include a primary power source 402. In some implementations, the primary power source 402 may comprise a current source configured to provide a current i₁. In some other implementations, the primary power source 402 may comprise a voltage source providing a voltage. Driving a current into the circuitry of the wireless power transmitter 420 may cause a voltage to appear across the terminals of the primary power source 402. The wireless power transmitter 420 includes a first capacitor 404 having a capacitance C₁, which may comprise or represent a resonant/tuning capacitor. During operation, a voltage v1 may appear across the terminals of the first capacitor 404. The wireless power transmitter 420 further includes a first resistance 406 having a resistance R₁, which may comprise or represent an intrinsic resistance of a primary coil (e.g., a transmit coil). The wireless power transmitter 420 further includes a first leakage inductance 408, having inductance L_{1S}, of the primary coil. The wireless power transmitter 420 further shares a mutual inductance 412, having an inductance L_{M}, with the wireless power receiver 430. The primary coil impedance may be represented by the combination of the first resistance 406, the first leakage inductance 408, and the mutual inductance 412. The first leakage inductance 408 is associated with portions of magnetic flux generated by the primary coil that do not couple with the secondary coil, while the mutual inductance 412 is associated with portions of the magnetic flux generated by the primary coil that do couple with the secondary coil. Driving current into the primary coil causes a voltage vL₁ to appear across the primary coil.

The wireless power receiver 430 includes a second leakage inductance 410, having an inductance of L_{2S}, of a secondary coil (e.g., a receive coil) and the mutual inductance 412 shared with the wireless power transmitter 420. The wireless power receiver 430 further includes a second resistance 414, which may comprise or represent an intrinsic resistance of the secondary coil. An alternating magnetic field generated by the primary coil when driven by the primary power source 402 may induce a voltage across the secondary coil. The secondary coil impedance may comprise the second resistance 414, the second leakage inductance 410 and the mutual inductance 412. Thus, the induced voltage vLm is shown as appearing across the series combination of the second resistance 414, the second leakage inductance 410 and the mutual inductance 412. The wireless power receiver 430 may further include a second capacitor 416, having a capacitance C₂, which may comprise or represent a resonant/tuning capacitor. The wireless power receiver 430 may further include a load 418, having a resistance R_{L}, which may comprise or represent all impedances loading the wireless power receiver 430, or alternatively, at least a battery configured to receive charging power.

The wireless power receiver 430 is shown having a parallel-parallel tuned topology. The parallel-parallel circuit is an example only, and not a limitation, as a series tuned circuit may also be used. In the parallel-parallel topology, the first capacitor 404 is shown in parallel with the primary coil, represented by the first resistance 406, the first leakage inductance 408 and the mutual inductance 412. Likewise, the second capacitor 416 is shown in parallel with the load 418 and the secondary coil, represented by the second resistance 414, the second leakage inductance 410 and the mutual inductance 412. Moreover, the values of L₂ₛ, R₂, C₂ and R_{L}, as well as the voltages appearing across them and/or currents passing through them, are represented as they would appear from the wireless power transmitter side (e.g., the primary side) since, in the physical implementation, the electrical components of the wireless power receiver 430 are electrically linked to the wireless power transmitter 420 via tightly or loosely coupled transformer action between the primary and secondary coils.

Although FIG. 4 shows a parallel-parallel tuned implementation, the present application is not so limited and also contemplates other configures such as series-series and parallel-parallel (partial series), and various combinations for either the wireless power transmitter 420 or the wireless power receiver 430. Moreover, various primary coil and secondary coil magnetics topology may also be utilized. Non-limiting examples of such magnetics topologies may include single coil arrangements, a plurality of coplanar coil arrangements, double-D (DD) coil arrangements, double-D quadrature (DDQ) coil arrangements, bipolar coil arrangements, or any other known or currently unknown magnetics topologies.

Electrical, mechanical and performance requirements for WEVC systems are highly individual to specific customer requirements. In general, magnetics design in a WEVC system is influenced by power electronics components like semiconductors, tuning elements and litz wire. The stress on these components must be considered during the magnetic design stage. For example, an acceptable level of stress on the power electronic components may be limited due to thermal, packaging, cost and system efficiency aspects. Accordingly, a feasibility check regarding power electronics/system stress is preferred prior to constructing and iterating through several prototypes. The power electronics/system feasibility of given WEVC magnetics may depend on many parameters such as magnetics coupling variation, inductance variation of the primary magnetics (i.e., the transmitter), inductance variation of the secondary magnetics (i.e., the receiver), and the quality factor (Q) of the resonant circuit in the secondary. These parameters may also interact with one another when the feasibility is evaluated (e.g., magnetics with a small inductance variation may have a larger secondary Q). With such a multi-dimensional parameter space, performing a feasibility check during the magnetic design phase may be complex. Prior solutions for determining the feasibility of a power control circuit required an initial definition of the number of turns in the respective coils (e.g., transmitter/receiver). This approach requires iterating through many values of input parameters, such as varying the fundamental inductance, since the turns value is discrete. Further, prototypes of these designs would have to be built and tested to confirm the feasibility of the power control circuit. This type of iterative design process often requires many man-hours of engineering, assembly and analysis and the associated increased financial cost.

Determining power electronics feasibility with single turn magnetic simulation data provides a more efficient and cost effective approach to power control circuit design as compared to prior solutions. The present application contemplates using the single turn results of magnetic FEM simulation data without determining turn counts. The feasibility determination is distilled down to the evaluation of two values: the computer aided determination of input (inverter) current variation, and the computer aided determination of the ratio of primary maximum real ampere-turns (AT) and primary ideal AT. The input current variation represents the accumulated system variation, including the coupling variation and the system detuning seen from the inverter. A feasibility limit value is established to determine a possible range of the power electronics capability. That is, the power electronics may handle increased coupling variation with decreased inductance variation, or decreased coupling variation but increased inductance variation. The feasibility limit value of the input current variation may vary based on specific wireless power transfer applications and other performance considerations, such as Z gap classes or different power classes. For WEVC applications, the input current variation limit value is approximately in the range of 2 to 2.5. The ratio of primary maximum real AT and primary ideal AT provides an indication about the maximum system detuning in the individual pads. In general, the base pad (BP) within a WEVC system is the most dominant system loss driver. A feasibility limit value is established to keep additional losses due to detuning with a certain range (e.g., 10%-20%). The ratio of primary maximum real AT and primary ideal AT identifies the net detuning/inductance variation in the resonant tanks in the power control circuit, even if the tanks partially compensate one another.

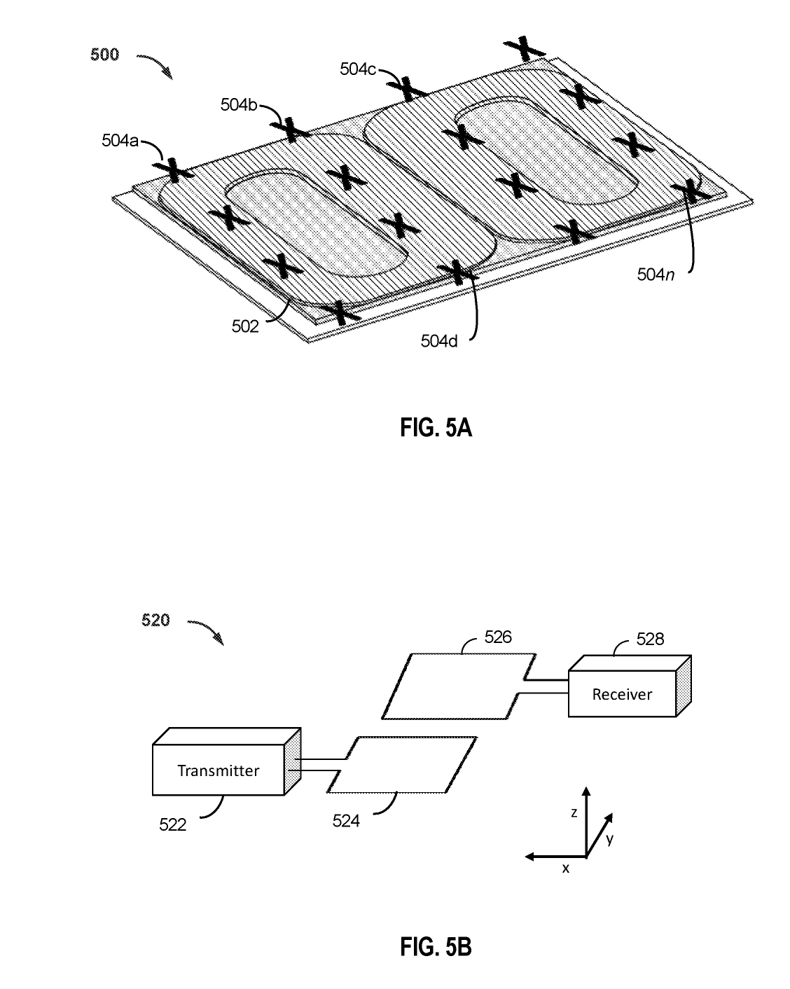

Referring to FIG. 5A, a conceptual diagram 500 of a base pad and examples of different offset positions are shown. The diagram 500 includes a base pad 502 and several examples of offset positions such as a first offset position 504a, a second offset position 504b, a third offset position 504c, a fourth offset position 504d, and so on up to an n^{th} offset position 504n. The base pad 502 is depicted in a double-D configuration, but this topology is an example only and not a limitation as other base pad topologies such as single coil arrangements, a plurality of coplanar coil arrangements, double-D quadrature (DDQ) coil arrangements, bipolar coil arrangements, or any other known or currently unknown magnetics topologies may be used. Each of the offset positions 504a-n represents a point or volume with different x/y/z coordinates. The locations of the offset position in the diagram 500 are examples only and are provided to help illustrate that a finite element method (FEM) may be used to model the magnetic flux generated by the base pad 502 at each of the offset positions. For example a finite element solver such as JMAG® may be used to determine the magnetic flux at each of the different offset positions. In general, this modeling is used to help determine the impact when the receiving coil is shifted in relation to the transmitting coil.

Referring to 5B, with further references to FIG. 2, a perspective diagram 520 of an example of a transmitter and an offset single loop receiver is shown. The diagram 520 includes a transmitter 522 and a receiver 528. The transmitter 522 is configured to provide power to a power transmitting element 524. In an example, the transmitter 522 is an example of the transmitter 204 in FIG. 2 and the power transmitting element 524 may be the base pad 502. The receiver 528 may be a receiver such as the receiver 208 in FIG. 2 and includes a power receiving element 526. The power receiving element 526 is a single loop that is disposed above and offset from the power transmitting element 524. For example, the power receiving element 526 may be centered about one of the offset positions 504a-n. In this example, the magnetic FEM simulation may be used to determine a coupling value with the power receiving element 526 for each of the offset locations.

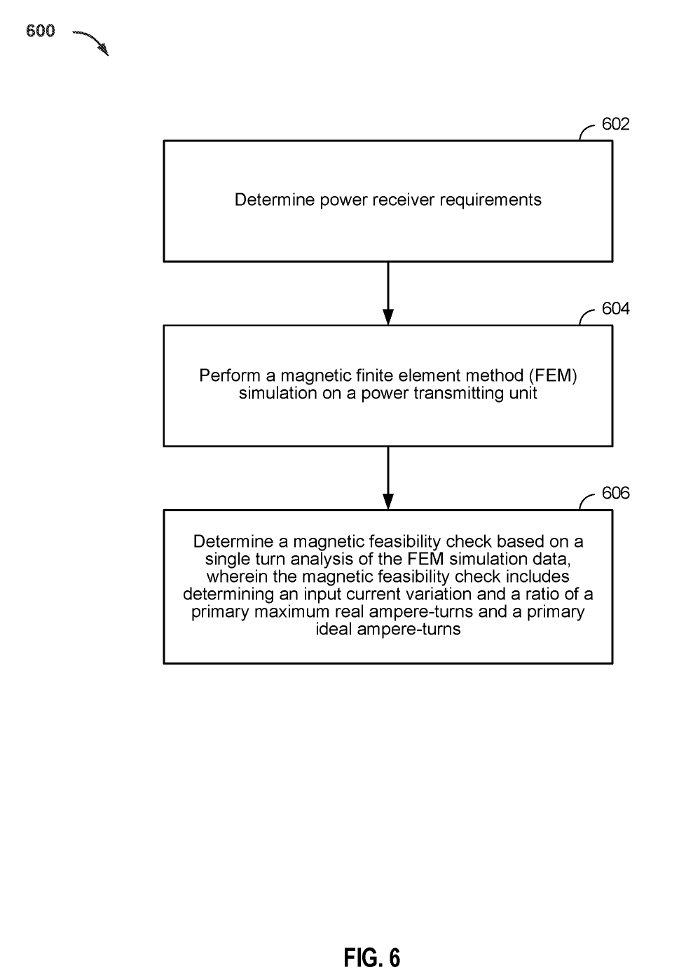

Referring to FIG. 6, an example of a process 600 of determining a magnetic feasibility check based on a single turn analysis of magnetic FEM simulation data is shown. The process 600 is, however, an example only and not limiting. The process 600 can be altered, e.g., by having stages added, removed, rearranged, combined, performed concurrently, and/or having single stages split into multiple stages.

At stage 602, the requirements for a power receiving unit (e.g., a receiver) are determined. The requirements may utilize computer modeling based on input parameters such as the available power input, efficiency and reliability, expected offset/Z gap range, battery voltage, transmitting and receiving pad dimensions, electromagnetic compatibility (EMC) and electric magnetic field (EMF) requirements. These parameters may be considered as the basic foundation of any wireless power transfer solution. Subsequent feasibility checks may be compared to the established requirements.

At stage 604, a finite element solver is used to perform a magnetic finite element (FEM) simulation on a power transmitting unit. The power transmitting unit may include a transmitter 204 and a power transmitting element 214. In an example, the magnetic FEM simulation is based on typical displacements of the receiver against the transmitter for different x/y/z offsets (e.g., 20-25 different offset positions 504a-n). These simulations model the expected inductances for the transmitter and the receiver, including the coupling between the transmitter and receiver and the necessary current to transfer an ideal power (e.g., 6.6 kW for WEVC applications, or other values as determined at stage 602). These parameters, the inductances, the coupling and the currents in the transmitter and the receiver are the input parameters to magnetic feasibility check.

At stage 606, at least one processor determines a magnetic feasibility check based on a single turn analysis of the FEM simulation data, such that the magnetic feasibility check includes determining an input current variation and a ratio of a primary maximum real ampere-turns and a primary ideal ampere-turns. Referring to FIG. 4, in an example circuit, the two capacitances C1 and C2 are fixed. Once the values for C1 and C2 are determined for one offset position, they must remain constant for each of the other offset locations. The example circuit must therefore support charging in all the different displacement conditions from the initial condition to all conditions that are theoretically possible (e.g., all of the 20-25 simulation input points). Once the input parameters from the FEM simulation are determined for all of the offset points, the objective is to try to find an electronic system that is feasible with that magnetic system. Accordingly, using the magnetic simulation as an input, two branches of calculations are made. In the first branch, the capacitance values for C1 and C2 are fixed based on the offset point with the lowest coupling. These capacitance values are then used to analyze the remaining electronic parameters at each of the other offset points. The use of the lowest coupling values is an example only, and not a limitation. In an example, the highest coupling power may be used as a reference. A variation of the real input current across each of the offset positions can be compared to a pre-established limit (e.g., less than 2.4) to determine if the power electronics within the circuit will be operating within specified limits for all offset positions. In the second branch, it is assumed that every single offset point can be tuned (e.g., with different C1 and C2 values), which results in an ideal tuned system at every offset point. This is a mathematical instrument used in the feasibility analysis because in a real circuit, the capacitance values on the circuit (e.g., on a PCB) typically are not changed for each offset (e.g., every time the receiver is in a different position relative to the transmitter). An indication of a difference (e.g., ratio, percentage difference) between the maximum real transmitter AT (i.e., with fixed values for C1 and C2) and the ideal AT (i.e., with different C1 and C2 values) is determined. The maximum percentage can be compared to a pre-established limit (e.g., less than 15%) to determine if the power electronic configuration will be operating within specified limits. The magnetic feasibility check based on the single turn analysis of the FEM simulation data does not require determining a ratio of turns between the transmitter and the receiver. The feasibility of the power electronics can be determined based solely on the calculation of the input current variation and the ratio of the transmitter maximum real AT and the ideal AT.

The process 600 can dramatically reduce the trial and error methods used in the prior art, and eliminates the need to model the number of turns required on the transmitter and receiver inductors.

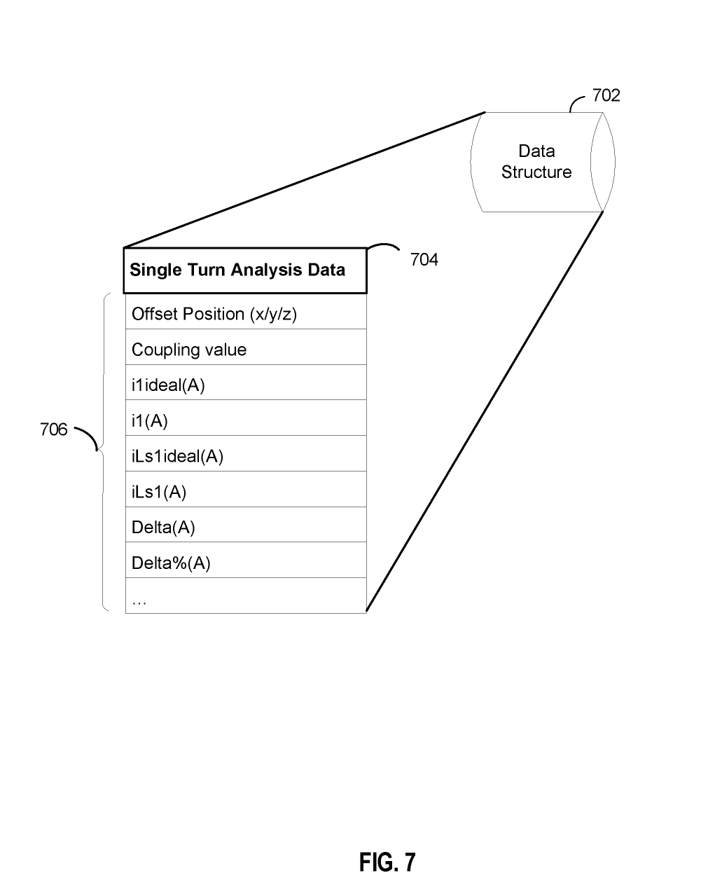

Referring to FIG. 7, with further reference to FIG. 4, a data structure 702 for determining power electronics feasibility with single turn magnetic simulation data is shown. The data structure 702 may be included in a computer system (not shown in FIG. 7) and operably coupled to one or more processors, memory, and associated peripheral devices. The data structure 702 is a data structure means for storing power electronics feasibility data and may be a non-transitory processor-readable storage medium. The data structure 702 may be a relational database (e.g., SQL, Oracle, dBase, etc.), one or more flat files (e.g., XML, Simple Object Access Protocol (SOAP), text, etc. . . . ), or other persistent media configured to store data. In an example, the data structure 702 may include one or more data tables 704. The data table 704 may include a collection of records, with each record including one or more data fields 706. The data fields 706, used for determining power electronics feasibility with single turn magnetic simulation data, may include the parametric values for the components in the parallel-parallel tuned wireless power transfer system 400. For example, the data fields 706 in each record may include an offset position (e.g., x/y/z coordinates), a coupling value, an ideal input current (e.g., i1ideal), a real input current (e.g., i1), an ideal current through the primary coil (e.g., iLs1ideal), a real current through the primary coil (e.g., iLs1), a delta value (e.g., the difference between iLs1ideal and iLs1), and a delta % value to indicate the ratio of the current between iLs1ideal and iLs1. In an example the data table 704 may include a first field containing data representing an offset position, a second field containing data representing an ideal input current, a third field containing data representing a real input current, a fourth field containing data representing an ideal current through a primary coil, and a fifth field containing data representing a real current through the primary coil. The data table 704 may include additional data fields associated with the components in the parallel-parallel tuned wireless power transfer system 400, such as real and ideal currents across C1 and C2, R1, R2, Ls2, and RL. Storing these additional data fields is optional as the feasibility determination may be made based solely on the input current variation (e.g., i1ideal, i1) and the ratio of the current between iLs1ideal and iLs1 (e.g., delta %).

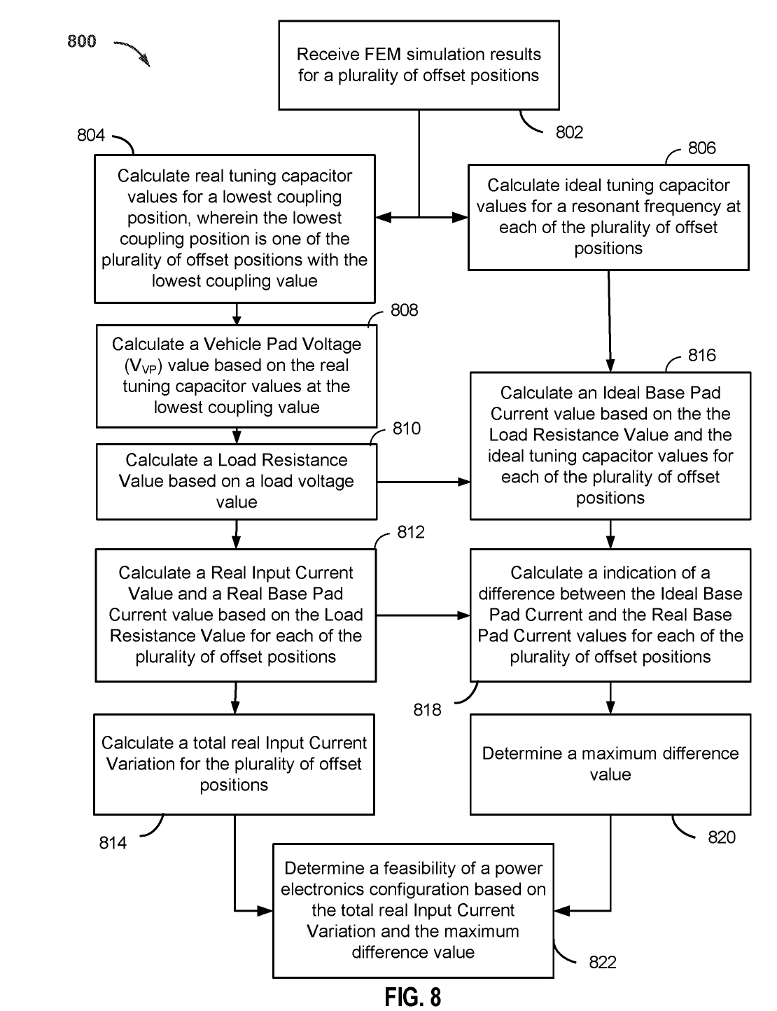

Referring to FIG. 8, an example of a process 800 for determining the feasibility of a power electronics configuration is shown. The process 800 is, however, an example only and not limiting. The process 800 can be altered, e.g., by having stages added, removed, rearranged, combined, performed concurrently, and/or having single stages split into multiple stages. The process 800 refers to a WEVC application and identifies the transmitting element as a base pad and the receiving element as a vehicle pad. The example calculations are based on the equivalent circuit diagram of a parallel-parallel tuned wireless power transfer system 400 in FIG. 4. The process 800, however, is not so limited as other tuned systems may be used for other wireless power transfer applications (e.g., implants, wearable devices, smart phones, tablets, laptops, etc.).

The process 800 utilizes magnetic FEM simulation results at typical displacements of a receiving element (e.g., a vehicle pad) against the transmitting element (e.g., base pad) for different x/y/z offsets (e.g., 20-25 different simulation points). These simulations provide inductance values for the transmitting element and the receiving element, the coupling between the elements, and the necessary current to transfer an ideal power (e.g., 6.6 kW for an example WEVC application). These parameters (i.e., the inductances, the coupling and the currents) in the transmitting element and the receiving element are the input parameters to calculate an electrical circuit that is capable of transferring power in reality. In an operational circuit (e.g., a real product), there are two capacitance values (i.e., C1 and C2) that need to be determined and will remain constant for each offset position. This operational circuit must support charging in a plurality of different displacement conditions (i.e., from the initial condition to other operationally probable conditions that are theoretically possible). Utilizing the input parameters for all of the offset locations, the process 800 may be used to determine an electronic system that is feasible with the modeled magnetic system. In general, using the magnetic simulation as an input, the process 800 includes two branches of calculations based on the equivalent circuit diagram of a parallel-parallel tuned wireless power transfer system 400. The first branch includes stages 804, 808, 810, 812 and 814. In the first branch, the capacitance values for C1 and C2 are fixed based on the offset point with the lowest coupling. These capacitance values are then used to analyze the remaining electronic parameters at each of the other offset points. A variation of the real input current across each of the offset positions can be compared to pre-established limits to determine if the power electronics within the circuit will be operating within specified limits for all offset positions. The second branch includes stages 806, 816, 818 and 820. In the second branch, it is assumed that every single offset point can be tuned (e.g., with different C1 and C2 values), which results in an ideal tuned system at every offset point. An indication of a difference between the ideal and real base pad currents can be determined, and the maximum difference can be compared to a pre-established limit (e.g., a difference threshold value) to determine if the power electronic configuration will be operating within specified limits.

In operation, at stage 802, a computer system receives FEM simulation results for a plurality of offset position. The computer system may include a finite element solver application such as JMAG® configured to determine magnetic FEM simulation results between a transmitting element 524 and a receiving element 526 at each of several different offset positions 504a-n. The number of different offset locations may vary based on the wireless power transfer application, transmitting element characteristics, and other performance requirements. For example, in a WEVC application, approximately 20-25 different offset positions may be used. The FEM simulation results for each offset location may include a coupling value (e.g., k₁₂), a transmitting element inductance value L_{BP} (e.g., L_{1S}+Lₘ), a receiving element inductance value L_{VP} (e.g., L_{2S}+Lₘ), and a receiving element current value I_{VP} (e.g., iL_{2S}). The offset position information (e.g., Cartesian, polar, or other coordinate information) and the corresponding FEM simulation results may be stored in a data structure 702 that is part of, or operably coupled to, the computer system.

At stage 804, the computer system calculates real tuning capacitor values for a lowest coupling position, wherein the lowest coupling position is one of the plurality of offset positions with the lowest coupling value. In a WEVC example, the value of the power out is set to 6.6 kW, and the operational frequency is set to 85 kHz. Other power and frequency values may be used for other wireless power transfer applications. Referring to FIG. 4, the values of C1 and C2 (i.e., the tuning capacitors) may be determined based on the transmitting and receiving element inductances (e.g., L_{BP} and L_{VP}) at the system resonant frequency of 85 kHz. In an example, the FEM simulation results assume fixed voltages over L_{VP} based on the parallel tuning/compensation of the power transfer system 400.

At stage 808, the computer system calculates a vehicle pad voltage (V_{VP}) value based on the real tuning capacitor values at the lowest coupling value. In the WEVC example, the vehicle pad is the receiving element 526. Using the values of C1 and C2 determined at stage 804, the computer calculates the necessary V_{VP} (e.g., vLm) value to achieve the receiving element current (e.g., I_{VP}/iL_{2S}) based on the receiving element inductance (e.g., L_{VP}/L_{2S}+Lₘ). At stage 810, the computer system calculates a load resistance value (e.g., R_{L} in FIG. 4) based on a load voltage value. The load resistance value calculation is an iterative process that depends on the load voltage and the vehicle pad ampere-turns. For example, the load resistance value is for a certain vehicle pad ampere-turns value, which is valid for a certain load voltage. The load resistance value is based on the V_{VP} value (e.g., determined at stage 808) and the power out value provided in the input data (e.g., 6.6 kW).

At stage 812, the computer system calculates a real load input current and a real base pad current value based on the load resistance value for each of the plurality of offset positions. Referring to FIG. 4, the real load input current is the value iRL and the base pad current value is iL_{1S}. These values are calculated for each of the offset positions. For the WEVC example, these results may be much larger than the expected operating parameters (e.g., 100-200 A) because the module does not utilize turn count information (i.e., it assumes a single loop). In an example, the real input current value and the real base pad current value for each offset point are saved in the data structure 702 (e.g., i1(A), iLs1(A)). The feasibility analysis is based on the relative values of the computed values for each of the offset positions (e.g., the variation of the real input current, the difference between an ideal base pad). Specifically, at stage 814, the computer calculates a total real input current variation for the plurality of offset positions. The total real input variation is the variation of the calculated real input current values across all of the offset positions.

At stage 806, the computer system calculates ideal tuning capacitor values for a resonant frequency at each of the plurality of offset positions. The tuning capacitors C1 and C2 are determined based on the inductances (i.e., L_{VP}, L_{BP}) for the given x/y/z offset positions at the desired resonant frequency (e.g., 85 kHz in the WEVC example). The values of C1 and C2 represent the ideal values for the system 400 at a particular offset location. The ideal values of C1 and C2 may change for each different offset position.

At stage 816, the computer calculates an ideal base pad current value based on the load resistance value and the ideal capacitor values for each of the plurality of offset positions. The ideal base pad current value (e.g., iL_{1S}) for each offset position is determined using the ideal C1 and C2 values computed at stage 806, and the V_{VP} (e.g., vLm) value determined at stage 810. The ideal base pad current values for each of the offset positions may be stored in the data structure 702 (e.g., iLs1ideal(A)).

At stage 818, the computer calculates an indication of a difference between the ideal base pad current value and the real base pad current value for each of the plurality of offset positions. In a WEVC application, a base pad is a transmitting element. That is, the computer calculates an indication of a difference between an ideal transmitting element current value and a real transmitting element current value for each of the plurality of offset positions based on the FEM simulation results. For example, the data structure 702 includes the real base pad current value (e.g., iLs1(A)) calculated at stage 812, and the ideal base pad current value (iLs1ideal(A)) calculated at stage 816. The computer may be configured to determine the difference between the two fields. In an example the difference value is a percentage difference between to the two fields. The difference value and the percentage difference may also be stored in the data structure (e.g., Delta(A), Delta%(A)). At stage 820, the computer determines a maximum difference value (i.e., based on the indication of the difference). For example, the maximum value in the Delta%(A) fields for all of the offset positions in the data structure 702 may be determined.

At stage 822, the computer determines the feasibility of a power electronics configuration based on the total real input current variation and the maximum difference value. For example, the computer may determine the power electronics feasibility based on the total real input current variation as compared to a total real input current variation threshold value, and the maximum difference value as compared to a maximum difference threshold value. The maximum difference value may be a maximum percentage difference value. The process 800 utilizes the FEM simulation data to model the anticipated stress on the power electronics in a receiver circuit. A circuit is feasible if the modeled stress on the power electronics is below threshold values. The process 800 distills the analysis down to two variables: the total real input current variation calculated at stage 814, and the maximum difference value determined at stage 820. The total real input current variation is the variation between maximum and minimum values of input current calculated for each offset taken into single turn analysis with fixed values of tuning capacitors (i.e., C1, C2), and the maximum difference value is the ratio of primary maximum real AT to primary ideal AT given as the highest difference in one offset point between base pad current calculated for fixed values of tuning capacitors C1, C2 (e.g. real base pad current values) and variable values of tuning capacitors C1, C2 (e.g., ideal base pad current values). In the WEVC example, the upper threshold for the total input current variation is in a range between 2.0 and 2.5 and the maximum difference threshold value is a maximum percentage difference threshold value in a range between 10%-20%. A circuit is determined to be feasible if these parameters are within these threshold values. A circuit is not feasible if either one, or both, of the parameters exceed these threshold values. The threshold values of 2.4 and 15% are examples only based on the parallel tuned/compensated WEVC system described above. Other threshold values for the total real input current variation and maximum difference values may be established based on other receiver circuit designs for other wireless power transfer applications.

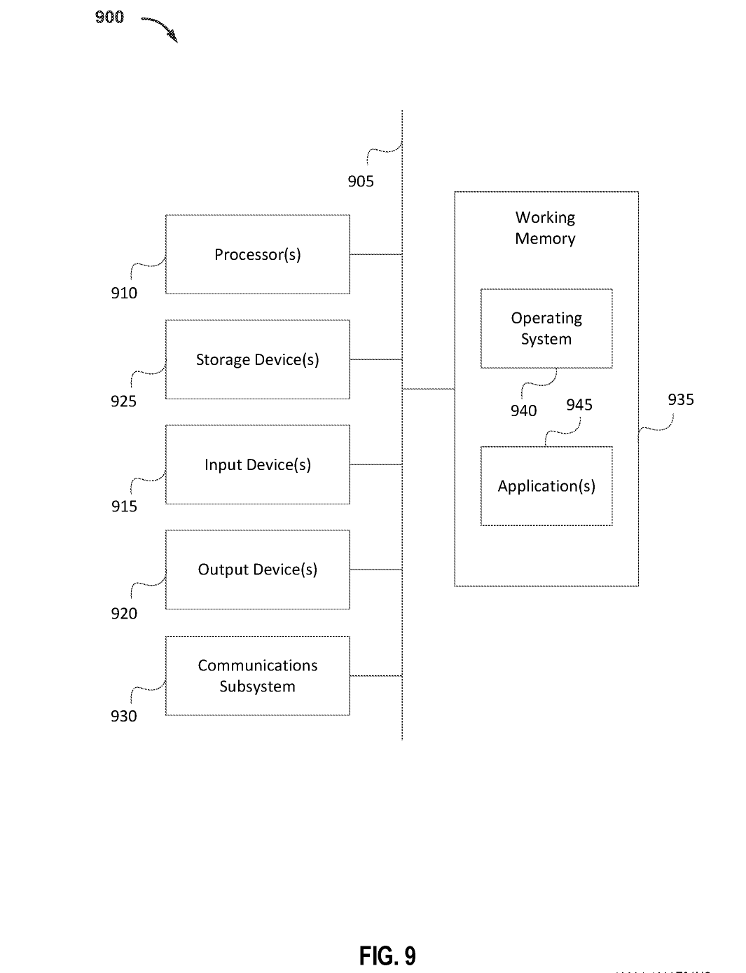

Referring to FIG. 9, with further reference to FIGS. 6-8, a computer system 900 may be utilized to determine power electronic feasibility with single turn magnetic simulation data, or to at least partially implement the functionality of some of the elements in FIGS. 6, 7 and 8. FIG. 9 provides a schematic illustration of one embodiment of a computer system 900 that can perform the methods provided by various other embodiments, as described herein. FIG. 9 provides a generalized illustration of various components, any or all of which may be utilized as appropriate. FIG. 9 therefore, broadly illustrates how individual system elements may be implemented in a relatively separated or relatively more integrated manner.

The computer system 900 is shown comprising hardware elements that can be electrically coupled via a bus 905 (or may otherwise be in communication, as appropriate). The hardware elements may include one or more processors 910, including without limitation one or more general-purpose processors and/or one or more special-purpose processors (such as digital signal processing chips, graphics acceleration processors, and/or the like); one or more input devices 915, which can include without limitation a mouse, a keyboard and/or the like; and one or more output devices 920, which can include without limitation a display device, a printer and/or the like. The processor(s) 910 can include, for example, intelligent hardware devices, e.g., a central processing unit (CPU) such as those made by Intel® Corporation or AMD®, a microcontroller, an ASIC, etc. Other processor types could also be utilized.

The computer system 900 may further include (and/or be in communication with) one or more non-transitory storage devices 925 configured as a non-transitory processor-readable storage medium, which can comprise, without limitation, local and/or network accessible storage, and/or can include, without limitation, a disk drive, a drive array, an optical storage device, solid-state storage devices such as a random access memory (“RAM”) and/or a read-only memory (“ROM”), which can be programmable, flash-updateable and/or the like. Such storage devices may be configured to implement any appropriate data stores, including without limitation, various file systems, database structures, and/or the like. For example, the storage device 925 may include the data structure 702 as local or networked accessible storage.

The computer system 900 may also include a communications subsystem 930, which can include without limitation a modem, a network card (wireless or wired), an infrared communication device, a wireless communication device and/or chipset (such as a Bluetooth short-range wireless communication technology transceiver/device, an 802.11 device, a WiFi device, a WiMax device, cellular communication facilities, etc.), and/or the like. The communications subsystem 930 may permit data to be exchanged with a network (such as the network described below, to name one example), other computer systems, and/or any other devices described herein. In many embodiments, the computer system 900 will further comprise, as here, a working memory 935, which can include a RAM or ROM device, as described above.

The computer system 900 can also comprise software elements, shown as being currently located within the working memory 935, including an operating system 940, device drivers, executable libraries, and/or other code, such as one or more application programs 945, which may comprise computer programs provided by various embodiments, and/or may be designed to implement methods, and/or configure systems, provided by other embodiments, as described herein. Merely by way of example, one or more processes described herein might be implemented as code and/or instructions executable by a computer (and/or a processor within a computer). Such code and/or processor-readable instructions can be used to configure and/or adapt a general purpose computer (or other device) to perform one or more operations in accordance with the described methods.

A set of these instructions and/or code might be stored on a computer-readable storage medium, such as the storage device(s) 925 described above. In some cases, the storage medium might be incorporated within a computer system, such as the computer system 900. In other embodiments, the storage medium might be separate from a computer system (e.g., a removable medium, such as a compact disc), and/or provided in an installation package, such that the storage medium can be used to program, configure and/or adapt a general purpose computer with the instructions/code stored thereon. These instructions might take the form of executable code, which is executable by the computer system 900 and/or might take the form of source and/or installable code, which, upon compilation and/or installation on the computer system 900 (e.g., using any of a variety of generally available compilers, installation programs, compression/decompression utilities, etc.) then takes the form of executable code.

Substantial variations may be made in accordance with specific desires. For example, customized hardware might also be used, and/or particular elements might be implemented in hardware, software (including portable software, such as applets, etc.), or both. Further, connection to other computing devices such as network input/output devices may be employed.

The computer system 900 may be used to perform methods in accordance with the disclosure. Some or all of the procedures of such methods may be performed by the computer system 900 in response to processor(s) 910 executing one or more sequences of one or more instructions (which might be incorporated into the operating system 940 and/or other code, such as an application programs 945) contained in the working memory 935. Such instructions may be read into the working memory 935 from another computer-readable medium, such as one or more of the storage device(s) 925. Merely by way of example, execution of the sequences of instructions contained in the working memory 935 might cause the processor(s) 910 to perform one or more procedures of the methods described herein.

The various operations of methods described above may be performed by any suitable means capable of performing the operations, such as various hardware and/or software component(s), circuits, and/or module(s). Generally, operations illustrated in the Figures may be performed by corresponding functional means capable of performing the operations.

The various illustrative logical blocks, modules, circuits, and algorithm steps described in connection with the implementations disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions should not be interpreted as causing a departure from the scope of the implementations.

Other examples and implementations are within the scope and spirit of the disclosure and appended claims. For example, due to the nature of software and computers, functions described above can be implemented using software executed by a processor, hardware, firmware, hardwiring, or a combination of any of these. Features implementing functions may also be physically located at various positions, including being distributed such that portions of functions are implemented at different physical locations.

Also, as used herein, “or” as used in a list of items prefaced by “at least one of” or prefaced by “one or more of” indicates a disjunctive list such that, for example, a list of “at least one of A, B, or C,” or a list of “one or more of A, B, or C” means A or B or C or AB or AC or BC or ABC (i.e., A and B and C), or combinations with more than one feature (e.g., AA, AAB, ABBC, etc.).

As used herein, unless otherwise stated, a statement that a function or operation is “based on” an item or condition means that the function or operation is based on the stated item or condition and may be based on one or more items and/or conditions in addition to the stated item or condition.

Further, an indication that information is sent or transmitted, or a statement of sending or transmitting information, “to” an entity does not require completion of the communication. Such indications or statements include situations where the information is conveyed from a sending entity but does not reach an intended recipient of the information. The intended recipient, even if not actually receiving the information, may still be referred to as a receiving entity, e.g., a receiving execution environment. Further, an entity that is configured to send or transmit information “to” an intended recipient is not required to be configured to complete the delivery of the information to the intended recipient. For example, the entity may provide the information, with an indication of the intended recipient, to another entity that is capable of forwarding the information along with an indication of the intended recipient.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations provides a description for implementing described techniques. Various changes may be made in the function and arrangement of elements without departing from the spirit or scope of the disclosure.

Also, configurations may be described as a process which is depicted as a flow diagram or block diagram. Although each may describe the operations as a sequential process, many of the operations can be performed in parallel or concurrently. In addition, the order of the operations may be rearranged. A process may have additional stages or functions not included in the figure. Furthermore, examples of the methods may be implemented by hardware, software, firmware, middleware, microcode, hardware description languages, or any combination thereof. When implemented in software, firmware, middleware, or microcode, the program code or code segments to perform the tasks may be stored in a non-transitory computer-readable medium such as a storage medium. Processors may perform the described tasks.

Components, functional or otherwise, shown in the figures and/or discussed herein as being connected or communicating with each other are communicatively coupled. That is, they may be directly or indirectly connected to enable communication between them.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of operations may be undertaken before, during, or after the above elements are considered. Accordingly, the above description does not bound the scope of the claims.

Further, more than one invention may be disclosed.

What is claimed is:

1. An apparatus for determining a power electronics feasibility in a wireless power transfer system including a transmitting element and a receiving element, comprising:
at least one processor configured to:
receive Finite Element Method (FEM) simulation results for a plurality of offset positions between the transmitting element and the receiving element;
calculate a total real input current variation for the plurality of offset positions based on the FEM simulation results;
calculate an indication of a difference between an ideal transmitting element current value and a real transmitting element current value for each of the plurality of offset positions based on the FEM simulation results;
determine a maximum difference value based on the indication of the difference for each of the plurality of offset positions; and
determine the power electronics feasibility based on the total real input current variation as compared to a total real input current variation threshold value, and the maximum difference value as compared to a maximum difference threshold value.

2. The apparatus of claim 1 wherein the total real input current variation threshold value is between 2.0 and 2.5 and the maximum difference threshold value is a maximum percentage difference value between 10% and 20%.

3. The apparatus of claim 1 wherein the at least one processor is further configured to calculate ideal tuning capacitor values for a resonant frequency at each of the plurality of offset positions to calculate the indication of the difference between the ideal transmitting element current value and the real transmitting element current value for each of the plurality of offset positions.

4. The apparatus of claim 1 wherein the at least one processor is further configured to calculate real tuning capacitor values for a lowest coupling position to calculate the total real input current variation for the plurality of offset positions.

5. The apparatus of claim 1 wherein the FEM simulation results includes a coupling value, a transmitting element inductance value, a receiving element inductance value, and a receiving element current value for each of the plurality of offset positions.

6. The apparatus of claim 1 further comprising a data structure operably connected to the at least one processor.

7. The apparatus of claim 6 wherein the data structure comprises:
a first field containing data representing an offset position;
a second field containing data representing an ideal input current;
a third field containing data representing a real input current;
a fourth field containing data representing an ideal current through the transmitting element; and
a fifth field containing data representing a real current through the transmitting element.

8. A method for determining power electronics feasibility in a wireless power transfer system, comprising:
determining a plurality of offset positions between a transmitting element and a receiving element;
receiving Finite Element Method (FEM) simulation results for the plurality of offset positions between the transmitting element and the receiving element;
calculating a total real input current variation for the plurality of offset positions based on the FEM simulation results;
calculating a difference between an ideal transmitting element current value and a real transmitting element current value for each of the plurality of offset positions based on the FEM simulation results;
determining a maximum difference value based on the difference for each of the plurality of offset positions; and
determining power electronics feasibility based on the total real input current variation as compared to a total real input current variation threshold value, and the maximum difference value as compared to a maximum difference threshold value.

9. The method of claim 8 wherein the wireless power transfer system is configured to provide a power out of 6.6 kW.

10. The method of claim 9 wherein the total real input current variation threshold value is between 2.0 and 2.5 and the maximum difference threshold value is a maximum percentage difference value between 10% and 20%.

11. The method of claim 8 wherein calculating the difference between the ideal transmitting element current value and the real transmitting element current value for each of the plurality of offset positions includes calculating ideal tuning capacitor values for a resonant frequency at each of the plurality of offset positions.

12. The method of claim 8 wherein calculating the total real input current variation for the plurality of offset positions includes calculating real tuning capacitor values for a lowest coupling position, wherein the lowest coupling position is one of the plurality of offset positions with a lowest coupling value.

13. The method of claim 8 wherein the FEM simulation results includes a coupling value, a transmitting element inductance value, a receiving element inductance value, and a receiving element current value for each of the plurality of offset positions.

14. The method of claim 8 further comprising storing the total real input current variation and the maximum difference value in a data structure.

15. The method of claim 14 wherein storing the maximum difference value includes storing a maximum percentage difference value in the data structure.

16. An apparatus for determining a power electronics feasibility in a wireless power transfer system including a transmitting element and a receiving element, the apparatus comprising:
means for receiving Finite Element Method (FEM) simulation results for a plurality of offset positions between the transmitting element and the receiving element;
means for calculating a total real input current variation for the plurality of offset positions based on the FEM simulation results;
means for calculating an indication of a difference between an ideal transmitting element current value and a real transmitting element current value for each of the plurality of offset positions based on the FEM simulation results;
means for determining a maximum difference value based on the indication of the difference for each of the plurality of offset positions; and
means for determining the power electronics feasibility based on the total real input current variation as compared to a total real input current variation threshold value, and the maximum difference value as compared to a maximum difference threshold value.

17. The apparatus of claim 16 wherein the total real input current variation threshold value is between 2.0 and 2.5 and the maximum difference threshold value is a maximum percentage difference value between 10% and 20%.

18. The apparatus of claim 16 comprising means for calculating ideal tuning capacitor values for a resonant frequency at each of the plurality of offset positions to calculate the indication of the difference between the ideal transmitting element current value and the real transmitting element current value for each of the plurality of offset positions.

19. The apparatus of claim 16 comprising means for calculating real tuning capacitor values for a lowest coupling position to calculate the total real input current variation for the plurality of offset positions.

20. The apparatus of claim 16 wherein the FEM simulation results includes a coupling value, a transmitting element inductance value, a receiving element inductance value, and a receiving element current value for each of the plurality of offset positions.

21. The apparatus of claim 16 further comprising a data structure means for storing a power electronics feasibility data.

22. The apparatus of claim 21 wherein the data structure means comprises:
a first field containing data representing an offset position;
a second field containing data representing an ideal input current;
a third field containing data representing a real input current;
a fourth field containing data representing an ideal current through the transmitting element; and
a fifth field containing data representing a real current through the transmitting element.

23. A non-transitory processor-readable storage medium comprising processor-readable instructions configured to cause a processor to determine power electronics feasibility in a wireless power transfer system, comprising:
code for determining a plurality of offset positions between a transmitting element and a receiving element;
code for receiving Finite Element Method (FEM) simulation results for the plurality of offset positions between the transmitting element and the receiving element;
code for calculating a total real input current variation for the plurality of offset positions based on the FEM simulation results;
code for calculating a difference between an ideal transmitting element current value and a real transmitting element current value for each of the plurality of offset positions based on the FEM simulation results;
code for determining a maximum difference value based on the difference for each of the plurality of offset positions; and
code for determining the power electronics feasibility based on the total real input current variation as compared to a total real input current variation threshold value, and the maximum difference value as compared to a maximum difference threshold value.

24. The storage medium of claim 23 wherein the wireless power transfer system is configured to provide a power out of 6.6 kW.

25. The storage medium of claim 24 wherein the total real input current variation threshold value is between 2.0 and 2.5 and the maximum difference threshold value is a maximum percentage difference value between 10% and 20%.

26. The storage medium of claim 23 wherein the code for calculating the difference between the ideal transmitting element current value and the real transmitting element current value for each of the plurality of offset positions includes code for calculating ideal tuning capacitor values for a resonant frequency at each of the plurality of offset positions.

27. The storage medium of claim 23 wherein the code for calculating the total real input current variation for the plurality of offset positions includes code for calculating real tuning capacitor values for a lowest coupling position, wherein the lowest coupling position is one of the plurality of offset positions with a lowest coupling value.

28. The storage medium of claim 23 wherein the FEM simulation results includes a coupling value, a transmitting element inductance value, a receiving element inductance value, and a receiving element current value for each of the plurality of offset positions.

29. The storage medium of claim 23 further comprising code for storing the total real input current variation and the maximum difference value in a data structure.

30. The storage medium of claim 29 wherein the code for storing the maximum difference value includes code for storing a maximum percentage difference value in the data structure.
